(19) United States
(12) Patent Application Publication
(10) Pub. No.: US 2026/0130056 A1
(43) Pub. Date: May 7, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Peng QIN, Kunshan (CN); Jinfang ZHANG, Hefei (CN); Yang YANG, Hefei (CN); Liusong NI, Hefei (CN)

(73) Assignees: Hefei Visionox Technology Co., Ltd., Hefei (CN); Visionox Technology Inc., Kunshan (CN)

(21) Appl. No.: 19/330,839

(22) Filed: Sep. 17, 2025

(30) Foreign Application Priority Data
Nov. 4, 2024 (CN) 202411571726.0

(51) Int. Cl. H10K 59/122

(52) U.S. Cl. CPC H10K 59/122

(57) ABSTRACT

A display panel includes a substrate, a first electrode layer having a number of first electrodes spaced apart from each other on one side of the substrate, and a pixel definition layer disposed on the first electrode layer and exposing a portion of the first electrode to form a pixel opening. The pixel definition layer covers edge portions of the first electrode. The pixel definition layer includes a number of sub-layers. At least one of the sub-layers has a thickness greater than a thickness of the first electrode.

### CROSS-REFERENCES TO RELATED APPLICATIONS

The present application claims priority to the Chinese Patent Application No. 202411571726.0, filed on Nov. 4, 2024, and the entire contents of the aforementioned application are hereby incorporated by reference in its entirety.

### FIELD

The present application relates to the field of display technology, and specifically relates to a display panel and a display device.

### BACKGROUND

In recent years, display products have achieved rapid development with continuously increasing aperture ratio and improving display effect. However, the reliability of display products still needs to be improved.

### SUMMARY

In view of this, embodiments of the present application provide a display panel and a display device, which are able to improve low reliability of display products.

An embodiment of a first aspect of the present application provides a display. The display panel includes a substrate; a first electrode layer including first electrodes spaced apart from each other on one side of the substrate; and a pixel definition layer disposed on the first electrode layer and exposing a portion of the first electrode to form a pixel opening, and the pixel definition layer covers edge portions of the first electrode; and the pixel definition layer includes sub-layers, and at least one of the sub-layers has a thickness greater than a thickness of the first electrode. The advantage is that: it ensures good step coverage of the at least one sub-layer, resulting in good film formation at the step climbing position without cracks, to improve the reliability of the display panel.

In some embodiments, the sub-layers are made of inorganic material.

In some embodiments, the sub-layers include a first sub-layer and a second sub-layer stacked sequentially in a direction away from the substrate; in one embodiment, ratios of the thickness of the first sub-layer and the thickness of the second sub-layer to the thickness of the first electrode are respectively within a range of 0.8 to 6.25; in one embodiment, the thickness of the first sub-layer is greater than or equal to 1000 μm and less than or equal to 5000 μm; in one embodiment, the thickness of the second sub-layer is greater than or equal to 500 μm and less than or equal to 3000 μm.

In some embodiments, the thickness of the first sub-layer is greater than the thickness of the first electrode; in one embodiment, the thickness of the first sub-layer is greater than or equal to 2000 μm and less than or equal to 5000 μm.

In some embodiments, the first sub-layer is in contact with the first electrode. The advantage is that it can ensure good step coverage of the first sub-layer, thus preventing cracks from forming when climbing steps at the edge portions of the first electrode. Meanwhile, the first sub-layer can compensate for the step height formed by the first electrode, reducing the step climbing difficulty for the second sub-layer.

In some embodiments, the thickness of the second sub-layer is greater than the thickness of the first electrode; in one embodiment, the thickness of the second sub-layer is greater than or equal to 1000 μm and less than or equal to 2500 μm.

In some embodiments, the first sub-layer has better film-forming property than the second inorganic sub-layer; and/or the second sub-layer has better etching resistance than the first inorganic sub-layer. The advantage is that the thickness requirement for the first sub-layer 131 is relatively low, which is conducive to product thinning. The second sub-layer has better etching resistance than the first sub-layer, which can simultaneously improve the etching resistance of the pixel definition layer and further improve the reliability of the display panel.

In some embodiments, the first sub-layer and the second sub-layer are made of different materials; in one embodiment, the material of the first sub-layer includes silicon nitride; in one embodiment, the material of the second sub-layer includes silicon oxide.

In some embodiments, the first electrode includes a first sub-electrode layer and a second sub-electrode layer stacked together, the first sub-electrode layer is located on a side of the second sub-electrode layer proximate to the substrate, and an orthogonal projection of the first sub-electrode layer on the substrate is located within a range of an orthogonal projection of the second sub-electrode layer on the substrate; in one embodiment, the first electrode further includes a third sub-electrode layer, and the third sub-electrode layer is located on a side of the second sub-electrode layer away from the substrate; in one embodiment, the first sub-electrode layer and the third sub-electrode layer are made of same material; in one embodiment, the thickness of the first sub-electrode layer is greater than the thickness of the third sub-electrode layer; in one embodiment, the material of the first sub-electrode layer includes ITO; in one embodiment, the material of the second sub-electrode layer includes Ag. The advantage is that in application scenarios where an undercut structure is formed on the sidewall of the first electrode, the pixel definition layer is more prone to cracks. By setting the thickness of at least one sub-layer in the pixel definition layer to be greater than the thickness of the first electrode, the probability of cracks can be reduced, improving the reliability of the display panel.

In some embodiments, a distance between an edge of an orthogonal projection of the first sub-electrode layer on the substrate and an edge of an orthogonal projection of the second sub-electrode layer on the substrate is greater than or equal to 0.1 μm and less than or equal to 1 μm.

In some embodiments, the pixel definition layer includes a groove, an opening of the groove is located on a side of the pixel definition layer away from the substrate, and an orthogonal projection of the groove on the substrate is located between first electrodes of adjacent sub-pixels.

In some embodiments, the display panel further includes an isolation structure located on a side of the pixel definition layer away from the substrate; the isolation structure is provided to form isolation openings, the pixel opening is located within the isolation opening; the display panel further includes a second electrode and a light-emitting layer, the second electrode is located on a side of the first electrode away from the substrate, the light-emitting layer is located between the first electrode and the second electrode, and adjacent light-emitting layers and adjacent second electrodes are disconnected at the isolation structure.

In some embodiments, the isolation structure includes a first portion and a second portion, the first portion is located on a side of the second portion proximate to the substrate, and the second portion extends outwardly along a side wall edge of the first portion; in one embodiment, the isolation structure further includes a third portion, the third portion is located on a side of the first portion proximate to the substrate, and the third portion extends outwardly along a side wall edge of the first portion.

In some embodiments, the pixel definition layer includes a groove, an opening of the groove is located on a side of the pixel definition layer away from the substrate, and an orthogonal projection of the groove on the substrate is located between adjacent first electrodes; an orthogonal projection of the first portion on the substrate is located within a range of an orthogonal projection of the groove on the substrate; or an orthogonal projection of the first portion on the substrate covers an orthogonal projection of the groove on the substrate.

In some embodiments, the display panel further includes an inorganic encapsulation portion located on a side of the second electrode away from the substrate; adjacent inorganic encapsulation portions are disconnected on a side of the isolation structure away from the substrate; in one embodiment, the display panel further includes an organic encapsulation layer located on a side of the inorganic encapsulation portion away from the substrate, and an orthogonal projection of the organic encapsulation layer on the substrate covers orthogonal projections of the inorganic encapsulation portion and the isolation structure on the substrate; in one embodiment, the display panel further includes an inorganic encapsulation layer located on a side of the organic encapsulation layer away from the substrate, and an orthogonal projection of the inorganic encapsulation layer on the substrate covers an orthogonal projection of the organic encapsulation layer on the substrate.

According to another embodiment of the present application, a display device is provided. The display includes the display panel according to any one of the above embodiments.

According to the display panel and display device provided by embodiments of the present application, since the pixel definition layer extends from the substrate to a side of edge portions of the first electrode away from the substrate, that is, the pixel definition layer climbs steps at the sidewalls of the first electrodes. By setting the thickness of at least one sub-layer in the pixel definition layer to be greater than the thickness of the first electrode, it can ensure that the at least one sub-layer has good step coverage, resulting in good film formation at the step climbing position without cracks, to improve the reliability of the display panel.

### BRIEF DESCRIPTION OF THE DRAWINGS

FIG. 1a is a structural schematic top view of a display panel according to a first embodiment of the present application;

FIG. 1b is a structural schematic cross-sectional view along line A1-A2 of the display panel shown in FIG. 1a;

FIG. 2 is a structural schematic cross-sectional view of a display panel according to a second embodiment of the present application;

FIG. 3 is a structural schematic cross-sectional view of a display panel according to a third embodiment of the present application;

FIG. 4 is a structural schematic cross-sectional view of a display panel according to a fourth embodiment of the present application;

FIG. 5 is a structural schematic cross-sectional view of a display panel according to a fifth embodiment of the present application;

FIG. 6 is a structural schematic cross-sectional view of a display panel according to a sixth embodiment of the present application;

FIG. 7 is a structural schematic cross-sectional view of a display panel according to a seventh embodiment of the present application;

FIG. 8 is a structural schematic cross-sectional view of a display panel according to an eighth embodiment of the present application; and

FIG. 9 is a schematic view of a display device according to an embodiment of the present application.

### DETAILED DESCRIPTION

In the related art, the display industry has achieved pixel-level encapsulation by replacing fine metal mask process with photolithography process, and improved the aperture ratio of products. However, cracks are likely to occur in the pixel definition layer of display products, which leads to moisture intrusion into the pixel area through these cracks, resulting in pixel failure and affecting the reliability of display products.

In view of this, embodiments of the present application provide a display panel and a display device. By configuring the pixel definition layer to include multiple sub-layers and setting the thickness of at least one sub-layer greater than the thickness of the first electrode of the light-emitting device covered by the pixel definition layer, it ensures that, at the position where the pixel definition layer extends from the substrate to cover the edge portions of the first electrode, the at least one sub-layer has a good performance of covering the steps and will not develop cracks due to the steps formed by the thickness of the first electrode, to improve the reliability of display products.

The following description of the embodiments of the present application will be clear and complete in conjunction with the accompanying drawings of the embodiments of the present application. Obviously, the described embodiments are only a part of the embodiments of the present application, rather than all embodiments.

In the drawings, the dimensions of layers and regions may be exaggerated for clarity of illustration. It can be understood that when a structure is described as being “on or under” another structure, it can be directly on or under the other structure, or there can be intermediate structures. The same reference numerals consistently indicate the same structures. The structures mentioned here include any of films, elements, devices, components, and assemblies.

When a structure is described as being “connected” to another structure, it can be directly connected to the other structure, or indirectly connected to the other structure with one or more intermediate structures placed between them.

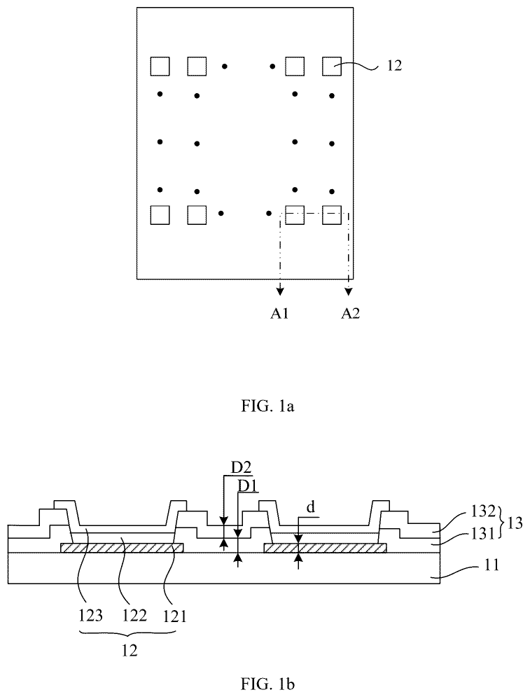

FIG. 1a is a top view of a display panel according to a first embodiment of the present application. FIG. 1b is a cross-sectional view along line A1A2 of the display panel shown in FIG. 1a. As shown in FIG. 1a and FIG. 1b, the display panel includes: a substrate 11, a first electrode layer, and a pixel definition layer 13. The first electrode layer includes first electrodes 121 spaced apart from each other on one side of the substrate 11. The pixel definition layer 13 is disposed on the first electrode layer and exposes a portion of the first electrode 121 to form a pixel opening. The pixel definition layer 13 covers edge portions of the first electrode 121. The pixel definition layer 12 includes sub-layers, and at least one of the sub-layers has a thickness greater than a thickness of the first electrode 121.

The substrate 11 can be a base substrate, or it can be an array substrate with pixel circuits disposed on a base substrate. For example, the base substrate can be a glass substrate. For example, the base substrate can include organic resin materials such as epoxy resin, triazine, silicone resin, or polyimide. For example, the base substrate can be an FR4 type Printed Circuit Board (PCB), or it can be a flexible PCB that is easily deformable. For example, the base substrate can include ceramic materials such as silicon nitride, aluminum nitride, or aluminum oxide, or include metal or metal compounds. For example, the pixel circuit can be a 7T1C pixel circuit, an 8T1C pixel circuit, etc.

The display panel further includes at least one light-emitting functional layer 122 and second electrodes 123. The corresponding first electrode 121, at least one light-emitting functional layer 122, and the second electrode 123 are stacked sequentially in a direction away from the substrate 11. The sequentially stacked first electrode 121, at least one light-emitting functional layer 122, and second electrode 123 form a sub-pixel 12.

The sub-pixel 12 can be an Organic Light-Emitting Diode (OLED), Micro Light-Emitting Diode (Micro LED), Quantum Dot Light Emitting Diodes (QLED), etc. The sub-pixel 12 can be light-emitting devices for emitting various colors, such as red light-emitting device R, green light-emitting device G, blue light-emitting device B, etc.

In one embodiment, the first electrode 121 is located on one side of the substrate 11, the pixel definition layer 13 is located between adjacent first electrodes 121, and extends from a position between adjacent first electrodes 121 to cover edge portions of the first electrode 121. The pixel definition layer 13 encloses to form pixel openings. The pixel openings expose the central portions of the first electrodes 121. The central portions of the first electrodes 121 are not covered by the pixel definition layer 13. For example, the first electrode 121 is an anode and the second electrode 123 is a cathode. In one embodiment, the first electrode 121 is a cathode and the second electrode 123 is an anode.

The at least one light-emitting functional layer 122 includes a light-emitting layer, and may also include at least one of a hole injection layer, a hole transport layer, and an electron blocking layer between the anode and the light-emitting layer, as well as at least one of an electron injection layer, an electron transport layer, and a hole blocking layer between the cathode and the light-emitting layer. For example, one or more layers among the hole injection layer, hole transport layer, electron blocking layer, hole blocking layer, electron transport layer, and electron injection layer of all sub-pixels 12 can be connected together as a common layer, and the light-emitting layers of adjacent sub-pixels 12 can be partially overlapped, or can be mutually isolated.

Since the pixel definition layer 13 extends from the substrate 11 to a side of edge portions of the first electrode 121 away from the substrate 11, that is, the pixel definition layer 13 climbs a step at the sidewall of the first electrode 121. By setting the thickness of at least one sub-layer in the pixel definition layer 13 to be greater than the thickness of the first electrode 121, it can ensure that the at least one sub-layer has good step coverage, resulting in good film formation at the step climbing position without cracks, to improve the reliability of the display panel.

In one embodiment, the material of the sub-layers is inorganic material.

In one embodiment, as shown in FIG. 1, the sub-layers include a first sub-layer 131 and a second sub-layer 132 stacked on the first sub-layer 131, with the first sub-layer 131 located on a side of the second sub-layer 132 proximate to the substrate 11. That is, the pixel definition layer 13 in this embodiment adopts a double-layer design.

For example, the first sub-layer 131 has better film-forming property than the second sub-layer 132. That is, under the same thickness conditions, the first sub-layer 131 can better cover the step structure formed by the first electrode 121, compared to the second sub-layer 132, without developing cracks. Conversely, to achieve the same step coverage effect, the thickness of the first sub-layer 131 is required to be thinner, than that of the second sub-layer 132. It helps to realize thinner-design of the product. Furthermore, good film-forming property is reflected in better coverage and higher density of the formed film, which is more beneficial for moisture isolation.

For example, the second sub-layer 132 has an etching resistance better than that of the first sub-layer 131. Since the side of the pixel definition layer 13 away from the substrate 11 will be etched during the display panel preparation process, by selecting a material with stronger etching resistance to form the second sub-layer 132, the etching resistance of the pixel definition layer 13 can be improved, further enhancing the reliability of the display panel.

For example, the first sub-layer 131 and the second sub-layer 132 are made of different materials. For instance, the material of the first sub-layer 131 includes silicon nitride, and the material of the second sub-layer 132 includes silicon oxide.

For example, a ratio of the thickness of the first sub-layer 131 to the thickness of the first electrode, and a ratio of the thickness of the second sub-layer 132 to the thickness of the first electrode, are respectively within a range of 0.8 to 6.25.

For example, the thickness D1 of the first sub-layer 131 is greater than or equal to 1000 μm and less than or equal to 5000 μm. For instance, the thickness D1 of the first sub-layer 131 can be 1000 μm, 2000 μm, 3000 μm, 4000 μm, 5000 μm, etc. It should be noted that when the thickness D1 of the first sub-layer 131 is within this range, the thickness D1 of the first sub-layer 131 may be greater than, less than, or equal to the thickness d of the first electrode 121.

For example, the thickness D2 of the second sub-layer 132 is greater than or equal to 500 μm and less than or equal to 3000 μm. For instance, the thickness D2 of the second sub-layer 132 can be 500 μm, 1000 μm, 2000 μm, 3000 μm, etc. It should be noted that when the thickness D2 of the second sub-layer 132 is within this range, the thickness D2 of the second sub-layer 132 may be greater than, less than, or equal to the thickness d of the first electrode 121.

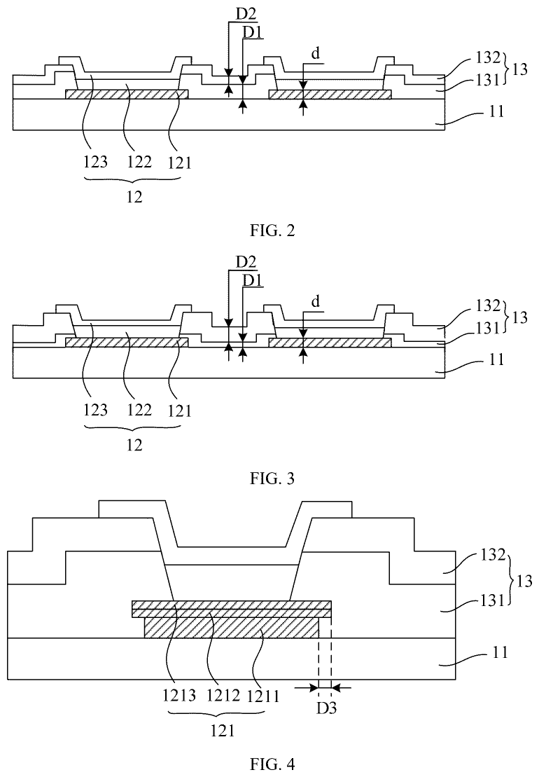

FIG. 2 is a cross-sectional view schematic diagram of a display panel according to a second embodiment of the present application. The difference between the display panel shown in FIG. 2 and the display panel shown in FIG. 1 is that in this embodiment, the thickness D1 of the first sub-layer 131 is greater than the thickness d of the first electrode 121.

In one embodiment, when the thickness D1 of the first sub-layer 131 is greater than the thickness d of the first electrode 121, the thickness D1 of the first sub-layer 131 is greater than or equal to 2000 μm and less than or equal to 5000 μm. For example, the thickness D1 of the first sub-layer 131 can be 2000 μm, 3000 μm, 4000 μm, 5000 μm, etc.

In one embodiment, the first sub-layer 131 is in contact with the first electrode 121. That is, by setting the thickness D1 of the first sub-layer 131 that contacts the first electrode 121 to be greater than the thickness d of the first electrode 121. It can ensure that the first sub-layer 131 has good step coverage. It can prevent cracks produced, when the first sub-layer 131 climbs steps at the edge portions of the first electrode 121. Meanwhile, the first sub-layer 131 can compensate for the step height formed by the first electrode 121, reducing the step climbing difficulty for the second sub-layer 122.

In one embodiment, the thickness D2 of the second sub-layer 132 is less than the thickness d of the first electrode 121.

FIG. 3 is a schematic cross-sectional view of a display panel according to a third embodiment of the present application. The difference between the display panel shown in FIG. 3 and the display panel shown in FIG. 1 is that in this embodiment, the thickness D2 of the second sub-layer 122 is greater than the thickness d of the first electrode 121.

In one embodiment, when the thickness D2 of the second sub-layer 132 is greater than the thickness d of the first electrode 121, the thickness D2 of the second sub-layer 132 is greater than or equal to 1000 μm and less than or equal to 2500 μm. For example, the thickness of the second sub-layer 132 can be 1000 μm, 1500 μm, 2000 μm, 2500 μm, etc.

In one embodiment, the thickness D1 of the first sub-layer 131 is less than the thickness d of the first electrode 121.

FIG. 4 is a schematic cross-sectional view of a display panel according to a fourth embodiment of the present application. As shown in FIG. 4, the difference between the display panel provided in this embodiment and the display panel provided in any of the above embodiments is that in this embodiment, the first electrode 121 includes a first sub-electrode layer 1211 and a second sub-electrode layer 1212 stacked together, the first sub-electrode layer 1211 is located on a side of the second sub-electrode layer 1212 proximate to the substrate 11, and an orthogonal projection of the first sub-electrode layer 1211 on the substrate 11 is located within a range of an orthogonal projection of the second sub-electrode layer 1212 on the substrate 11. That is, an inwardly recessed groove is formed on the sidewall of the first electrode 121. In this case, the pixel definition layer 13 is more prone to produce cracks when climbing steps at the sidewalls of the first electrodes 121. According to the display panel provided in this embodiment, by setting the thickness of at least one sub-layer in the pixel definition layer 13, such as the first sub-layer 131 and/or the second sub-layer 132, to be greater than the thickness of the first electrode 121, cracks in the at least one sub-layer can be avoided, to improve the reliability of the display panel.

In one embodiment, the first electrode 121 further includes a third sub-electrode layer 1213, and the third sub-electrode layer 1213 is located on a side of the second sub-electrode layer 1212 away from the substrate 11. For example, the first sub-electrode layer 1211 and the third sub-electrode layer 1213 are made of same material. For instance, the material of the first sub-electrode layer 1211 and the third sub-electrode layer 1213 includes ITO (Indium Tin Oxide), and the material of the second sub-electrode layer 1212 includes Ag. For example, the thickness of the first sub-electrode layer 1211 is greater than the thickness of the third sub-electrode layer 1213. In this case, during the patterning process of the first electrode 121, the side etching depth of the first sub-electrode layer 1211 is greater than that of the third sub-electrode layer 1213, while the side etching depth of the second sub-electrode layer 1212 is similar to that of the third sub-electrode layer 1213.

In one embodiment, a distance D3 between an edge of an orthogonal projection of the first sub-electrode layer 1211 on the substrate 11 and an edge of an orthogonal projection of the second sub-electrode layer 1212 on the substrate 11 is greater than or equal to 0.1 μm and less than or equal to 1 μm. For example, the distance D3 can be 0.3 μm, 0.5 μm, 0.7 μm, etc.

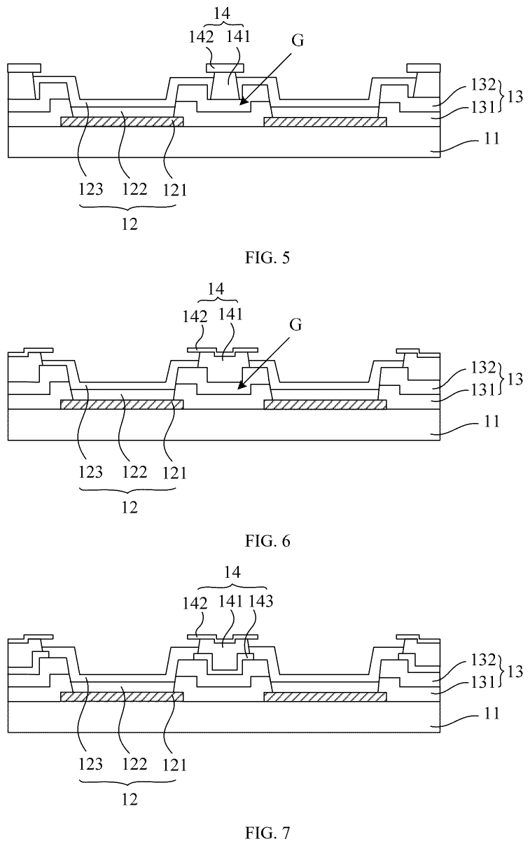

FIG. 5 is a schematic cross-sectional view of a display panel according to a fifth embodiment of the present application. As shown in FIG. 5, in this embodiment, the pixel definition layer 13 includes a groove G, an opening of the groove G is located on a side of the pixel definition layer 13 away from the substrate 11, and an orthogonal projection of the groove G on the substrate 11 is located between adjacent first electrodes 121. In this embodiment, the pixel definition layer 13 is a composite film layer of stacked multiple film layers, all of which are inorganic layers. Due to the limitations of inorganic layer film-forming process, the thickness of the pixel definition layer 13 is uniform. In this case, the distance between the portion of the pixel definition layer 13 located between adjacent first electrodes 121 and the substrate 11 is less than the distance between the portion of the pixel definition layer 13 located on a side of the first electrode 121 away from the substrate 11 and the substrate 11, to form a groove G in the pixel definition layer 13 between adjacent first electrodes 121.

In this embodiment, as shown in FIG. 5, the display panel further includes an isolation structure 14 located on a side of the pixel definition layer 13 away from the substrate 11. The isolation structure 14 encloses to form isolation openings, with the pixel opening located within the isolation opening. The display panel further includes a second electrode 123 and a light-emitting layer, with the second electrode 123 located on a side of the first electrode 121 away from the substrate 11, and the light-emitting layer located between the first electrode 121 and the second electrode 123. Adjacent light-emitting layers and adjacent second electrodes 123 are respectively disconnected at the isolation structure 14.

In one embodiment, the isolation structure 14 encloses to form multiple isolation openings, which communicate with the pixel openings, and an orthogonal projection of the isolation opening on the substrate 11 covers an orthogonal projection of the pixel opening on the substrate 11. The isolation structure 14 has an isolation function, used to disconnect at least one light-emitting functional layer 122 and the second electrode 123 of adjacent sub-pixels 12.

In one embodiment, the isolation structure 14 includes a first portion 141 and a second portion 142. The first portion 141 is located on a side of the second portion 142 proximate to the substrate 11, and the second portion 142 extends outward along side wall edges of the first portion 141. In this case, the cross-sectional shape of the isolation structure 14 can be T-shaped. The first portion 141 can be designed as an independent film layer. It means there is no physical interface within the first portion 141, and all parts are made of the same material. In one embodiment, the first portion 141 can be designed to be formed by stacking at least two film layers. For example, the first portion 141 is formed by stacking two conductive film layers. The materials of these two conductive film layers can be molybdenum and aluminum respectively, with the conductive film layer made of molybdenum located between the substrate 11 and the conductive film layer made of aluminum. The material of the second portion 142 can be inorganic material, organic material, or metallic material. When the second portion 142 is made of metallic material, the material of the second portion 142 can be titanium.

In one embodiment, the isolation structure 14 includes a conductive portion, for example, the first portion 141 is the conductive portion. The second electrode 123 overlaps with the conductive portion to achieve electrical connection between second electrodes 123 of adjacent sub-pixels 12.

As shown in FIG. 5, in this embodiment, an orthogonal projection of the first portion 141 on the substrate 11 is located within a range of an orthogonal projection of the groove G on the substrate 11. In this case, the first portion 141 has better flatness, and in the thickness direction of the substrate 11, there is no overlap between the first portion 141 and the first electrode 121, to reduce the coupling capacitance between the first portion 141 and the first electrode 121.

FIG. 6 is a schematic cross-sectional view of a display panel according to a sixth embodiment of the present application. The difference between the display panel shown in FIG. 6 and the display panel shown in FIG. 5 is that in this embodiment, an orthogonal projection of the first portion 141 on the substrate 11 covers an orthogonal projection of the groove G on the substrate 11.

FIG. 7 is a schematic cross-sectional view of a display panel according to a seventh embodiment of the present application. The difference between the display panel shown in FIG. 7 and the display panels shown in FIG. 5 and FIG. 6 is that, taking the display panel shown in FIG. 6 as an example, the isolation structure 14 in the display panel provided in this embodiment further includes a third portion 143 in addition to the isolation structure 14 in the display panel shown in FIG. 6. The third portion 143 is located on a side of the first portion 141 proximate to the substrate 11, and the third portion 143 extends outwardly along side wall edges of the first portion 141. In this case, the cross-sectional shape of the isolation structure 14 can be I-shaped.

For example, the material of the third portion 143 is aluminum. In this case, the first portion 141 can be an independent film layer, and the material of the first portion 141 can be molybdenum.

The composition, preparation, etc. of the isolation structure (also called isolation structure) 14 are further described in patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, CN117500332A, the contents of which are incorporated herein by reference.

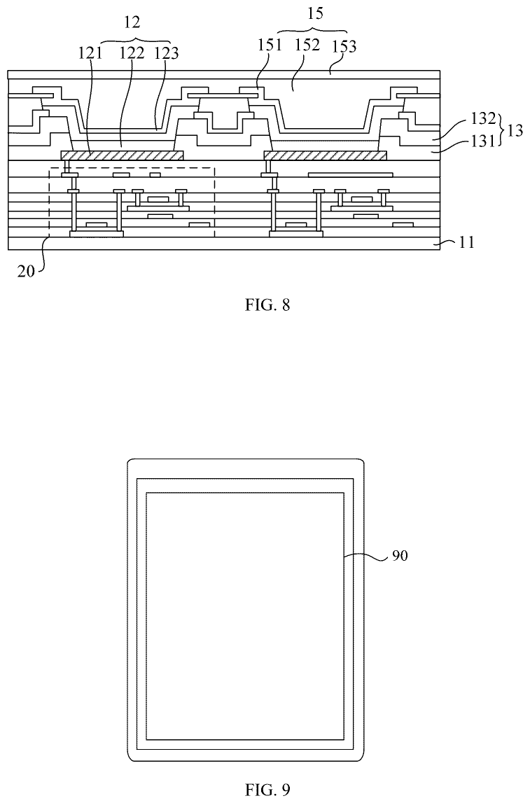

FIG. 8 is a cross-sectional view of a display panel according to an eighth embodiment of the present application. The difference between the display panel shown in FIG. 8 and the display panel provided in any of the above embodiments is that in this embodiment, the display panel further includes an inorganic encapsulation portion 151 located on a side of the second electrode 123 away from the substrate 11. Adjacent inorganic encapsulation portions 151 are disconnected on a side of the isolation structure 14 away from the substrate 11. For example, the inorganic encapsulation portions 151 one-to-one correspond e with the sub-pixels 12.

In one embodiment, the display panel further includes an organic encapsulation layer 152 located on a side of the inorganic encapsulation portion 151 away from the substrate 11, and an orthogonal projection of the organic encapsulation layer 152 on the substrate 11 covers orthogonal projection of the inorganic encapsulation portion 151 and orthogonal projection of the isolation structure 14 on the substrate 11.

In one embodiment, the display panel further includes an inorganic encapsulation layer 153 located on a side of the organic encapsulation layer 152 away from the substrate 11, and an orthogonal projection of the inorganic encapsulation layer 153 on the substrate 11 covers an orthogonal projection of the organic encapsulation layer 152 on the substrate 11.

In one embodiment, the display panel further includes a pixel circuit 20 located between the sub-pixel 12 and the substrate 11. The pixel circuit 20, for example, is a 7T1C pixel circuit.

The present application also provides a display device. FIG. 9 is a schematic diagram of a display device according to an embodiment of the present application. As shown in FIG. 9, the display device 90 includes the display panel provided in any of the above embodiments.

The display device 90 is a product having image display function. For example, the display device 70 can be used to display static images, such as pictures or photos. The display device 70 can also be used to display dynamic images, such as videos.

The display device 90 can be a laptop computer, mobile phone, handheld or portable computer, camera, video camera, vehicle intelligent central control screen, calculator, smart watch, GPS navigator, electronic photo, electronic billboard or sign, projector, etc.

The display device 90 can also have functions such as photography, video recording, fingerprint recognition, face recognition, etc. Accordingly, the display device 90 also includes at least one functional module for implementing the above functions, such as an under-screen camera, an under-screen fingerprint recognition sensor, etc.

The basic principles of the present application have been described above in conjunction with some embodiments. However, it should be noted that the advantages, benefits, effects, etc. mentioned in the present application are only examples and not limitations, and these advantages, benefits, effects, etc. should not be considered as necessary features for each embodiment of the present application. Additionally, the specific details disclosed above are for exemplary purposes and ease of understanding, not for limitation, and these details do not restrict the present application to necessarily adopt these specific details for implementation.

The above description has been given for illustrative and descriptive purposes. Furthermore, this description is not intended to limit the embodiments of the present application to the forms disclosed herein. Although multiple exemplary aspects and embodiments have been discussed above, certain variations, modifications, changes, additions, and sub-combinations thereof may be made.

What is claimed is:

1. A display panel, comprising:
a substrate;
a first electrode layer, comprising a plurality of first electrodes spaced apart from each other on one side of the substrate; and
a pixel definition layer, disposed on the first electrode layer and exposing a portion of the first electrode to form a pixel opening, the pixel definition layer covering an edge portion of the first electrode;
wherein the pixel definition layer comprises a plurality of sub-layers, and at least one of the sub-layers has a thickness greater than a thickness of the first electrode.

2. The display panel according to claim 1, wherein the sub-layers are made of inorganic material.

3. The display panel according to claim 1, wherein the plurality of sub-layers comprise a first sub-layer and a second sub-layer stacked sequentially in a direction away from the substrate.

4. The display panel according to claim 3, wherein a ratio of the thickness of the first sub-layer to the thickness of the first electrode, and another ratio of the thickness of the second sub-layer to the thickness of the first electrode, are respectively within a range of 0.8 to 6.25.

5. The display panel according to claim 4, wherein the thickness of the first sub-layer is greater than the thickness of the first electrode.

6. The display panel according to claim 5, wherein the first sub-layer is in contact with the first electrode.

7. The display panel according to claim 4, wherein the thickness of the second sub-layer is greater than the thickness of the first electrode.

8. The display panel according to claim 4, wherein the second sub-layer has an etching resistance greater than that of the first sub-layer.

9. The display panel according to claim 4, wherein the first sub-layer and the second sub-layer are made of different materials.

10. The display panel according to claim 1, wherein the first electrode comprises a first sub-electrode and a second sub-electrode arranged in a stacked manner, the first sub-electrode is located on a side of the second sub-electrode proximate to the substrate, and an orthogonal projection of the first sub-electrode on the substrate is located within a range of an orthogonal projection of the second sub-electrode on the substrate.

11. The display panel according to claim 10, wherein the first electrode further comprises a third sub-electrode, and the third sub-electrode is located on a side of the second sub-electrode away from the substrate.

12. The display panel according to claim 10, wherein the first sub-electrode and the third sub-electrode are made of a same material.

13. The display panel according to claim 10, wherein a distance between an edge of an orthogonal projection of the first sub-electrode on the substrate and an edge of an orthogonal projection of the second sub-electrode on the substrate is greater than or equal to 0.1 μm and less than or equal to 1 μm.

14. The display panel according to claim 1, wherein the pixel definition layer comprises a groove, an opening of the groove is located on a side of the pixel definition layer away from the substrate, and an orthogonal projection of the groove on the substrate is located between adjacent first electrodes.

15. The display panel according to claim 1, further comprising an isolation structure located on a side of the pixel definition layer away from the substrate,
wherein the isolation structure is provided to form a plurality of isolation openings, the pixel opening is located within the isolation opening;
the display panel further comprises a second electrode and a light-emitting layer, the second electrode is located on a side of the first electrode away from the substrate, the light-emitting layer is located between the first electrode and the second electrode; adjacent light-emitting layers and adjacent second electrodes are disconnected at the isolation structure.

16. The display panel according to claim 15, wherein the isolation structure comprises a first portion and a second portion, the first portion is located on a side of the second portion proximate to the substrate, and the second portion extends outwardly along a side wall edge of the first portion.

17. The display panel according to claim 16, wherein the isolation structure further comprises a third portion, the third portion is located on a side of the first portion proximate to the substrate, and the third portion extends outwardly along a side wall edge of the first portion.

18. The display panel according to claim 16, wherein the pixel definition layer comprises a groove, an opening of the groove is located on a side of the pixel definition layer away from the substrate, and an orthogonal projection of the groove on the substrate is located between adjacent first electrodes;
an orthogonal projection of the first portion on the substrate is located within a range of an orthogonal projection of the groove on the substrate; or
an orthogonal projection of the first portion on the substrate covers an orthogonal projection of the groove on the substrate.

19. The display panel according to claim 15, further comprising an inorganic encapsulation portion located on a side of the second electrode away from the substrate; adjacent inorganic encapsulation portions are disconnected on a side of the isolation structure away from the substrate.

20. A display device, comprising:
a display panel, comprising:
a substrate;
a first electrode layer, comprising a plurality of first electrodes spaced apart from each other on one side of the substrate; and
a pixel definition layer, disposed on the first electrode layer and exposing a portion of the first electrode to form a pixel opening, the pixel definition layer covering an edge portion of the first electrode;
wherein the pixel definition layer comprises a plurality of sub-layers, and at least one of the sub-layers has a thickness greater than a thickness of the first electrode.
